(19) United States
(12) Patent Application Publication
(10) Pub. No.: US 2026/0210445 A1
(43) Pub. Date: Jul. 23, 2026

(54) CLOSURE ASSEMBLY FOR A VACUUM VALVE

(71) Applicant: VAT HOLDING AG, Haag (CH)

(72) Inventors: Peter ZVOKELJ, Höchst (AT); Martin NETZER, Bludenz (AT)

(21) Appl. No.: 19/114,353

(22) PCT Filed: Sep. 22, 2023
(86) PCT No.: PCT/EP2023/076191

§ 371 Date: Mar. 21, 2025

(30) Foreign Application Priority Data
Sep. 23, 2022 (DE) 10 2022 003 517.0

(51) Int. Cl. F16K 3/314; F16K 3/18; F16K 51/02

(52) U.S. Cl. CPC F16K 3/314; F16K 3/18; F16K 51/02

(57) ABSTRACT

An aspect includes a vacuum valve having a valve seat, a closure assembly and a drive unit coupled to the closure assembly. The closure assembly has a carrier element having a first connection side and a closure plate having a second connection side, and the first and second connection sides are designed to connect the carrier element to the closure plate, having a support and a retaining element. The closure plate is brought together with the carrier element and the support and the retaining element are designed to correspond in such a way that a clamping force, which is directed orthogonally to an extension of at least one of the connection sides, is generated by an interaction of the support with the retaining element in the brought-together state, and the retaining element projects from the respective connection side and has a curved boundary line for interaction with the support.

The invention relates to a closure assembly for a vacuum valve, which closure assembly comprises a carrier element and a removable closure plate, and a connection system for attaching the closure plate to the carrier element.

In general, valves are designed to adjust a flow, especially of a fluid. With a valve, the flow can be allowed or completely shut off over a maximum valve opening cross-section. In addition, certain types of valves offer the possibility of regulating a flow rate per unit of time, i.e. they provide the ability to regulate a fluid flow.

Vacuum valves are a specific type of valve. These are known in various embodiments from the prior art for the regulation of a volume or mass flow and/or for the essentially gas-tight closure of a flow path leading through an opening formed in a valve housing and are used in particular in vacuum chamber systems in the field of IC, semiconductor or substrate production, which must take place in a protected atmosphere as far as possible without the presence of contaminating particles.

Such vacuum chamber systems comprise in particular at least one evacuable vacuum chamber provided for accommodating semiconductor elements or substrates to be processed or manufactured, which vacuum chamber has at least one vacuum chamber opening through which the semiconductor elements or other substrates can be guided into and out of the vacuum chamber, and at least one vacuum pump for evacuating the vacuum chamber.

For example, in a production system for semiconductor wafers or liquid crystal substrates, the highly sensitive semiconductor or liquid crystal elements sequentially pass through a plurality of process vacuum chambers in which the parts located within the process vacuum chambers are processed in each case by means of a processing device. Both during the processing process within the process vacuum chambers and during transport from chamber to chamber, the highly sensitive semiconductor elements or substrates must always be in a protected atmosphere, in particular in an airless environment.

For this purpose, peripheral valves are used on the one hand to open and close a gas inlet or outlet, and on the other hand transfer valves are used to open and close the transfer openings of the vacuum chambers for feeding and discharging the parts.

The vacuum valves through which semiconductor parts pass are known as vacuum transfer valves because of the field of application described and the associated dimensioning, also as rectangular valves because of their mostly rectangular opening cross-section, and also as slide valves, rectangular slide valves or transfer slide valves because of their usual mode of operation.

Peripheral valves are used in particular to control or regulate the gas flow between a vacuum chamber and a vacuum pump or a further vacuum chamber. Peripheral valves are located, for example, within a pipe system between a process vacuum chamber or a transfer chamber and a vacuum pump, the atmosphere or a further process vacuum chamber. The opening cross-section of such valves, also called pump valves, is usually smaller than that of a vacuum transfer valve. Since, depending on the application, peripheral valves are used not only to fully open and close an opening, but also to control or regulate a flow by continuously adjusting the opening cross-section between a fully open position and a gas-tight closed position, they are also referred to as control valves. One possible peripheral valve for controlling or regulating the gas flow is the pendulum valve.

In a typical pendulum valve, as known for example from U.S. Pat. No. 6,089,537 (Olmsted), in a first step a generally round valve disk is rotationally pivoted over a generally also round opening from a position exposing the opening to an intermediate position covering the opening. In the case of a slide valve, as described for example in U.S. Pat. No. 6,416,037 (Geiser) or U.S. Pat. No. 6,056,266 (Blecha), the valve disk, like the opening, is usually rectangular in shape and is pushed linearly in this first step from a position uncovering the opening into an intermediate position covering the opening. In this intermediate position, the valve disk of the pendulum or slide valve is in a spaced opposing position to the valve seat surrounding the opening. In a second step, the distance between the valve disk and the valve seat is reduced so that the valve disk and the valve seat are uniformly pressed against each other and the opening is closed in a substantially gas-tight manner. This second movement is preferably in a direction substantially perpendicular to the valve seat.

The sealing can be carried out, for example, either via a sealing ring arranged on the closing side of the valve disk, which is pressed onto the valve seat surrounding the opening, or via a sealing ring on the valve seat, against which the closing side of the valve disk is pressed. Due to the closing process taking place in two steps, the sealing ring between the valve disk and the valve seat is hardly subjected to shear forces which would destroy the sealing ring, since the movement of the valve disk in the second step takes place essentially in a straight line perpendicular to the valve seat.

Various sealing devices are known from the prior art, for example from U.S. Pat. No. 6,629,682 B2 (Duelli), A suitable material for sealing rings and seals in vacuum valves is, for example, fluororubber, also known as FKM, in particular the fluoroelastomer known under the trade name “Viton”, as well as perfluorubber, FFKM for short.

Various drive systems for achieving this combination of a rotational movement of the valve disk parallel across the opening in the case of a pendulum valve and a translational movement of the valve disk perpendicular to the opening in the case of a slide valve are known from the prior art, for example from U.S. Pat. No. 6,089,537 (Olmsted) for a pendulum valve and from U.S. Pat. No. 6,416,037 (Geiser) for a slide valve.

Particularly for vacuum applications, the valve disk must be pressed onto the valve seat in such a way that both the required gas tightness within the entire pressure range is ensured and damage to the sealing medium, in particular the sealing material or sealing ring (e.g. O-ring), due to excessive pressure stress, is avoided. In order to ensure this, known valves provide for a controlled contact pressure regulation of the valve disk depending on the pressure difference prevailing between the two valve disk sides. However, especially in the case of large pressure fluctuations or the change from negative pressure to positive pressure, or vice versa, an even distribution of force along the entire circumference of the sealing ring cannot always be guaranteed. In general, however, the aim is to decouple the sealing ring from support forces resulting from the pressure applied to the valve.

In the course of the operating life of a vacuum valve, changes in valve components can typically occur due to wear of the sealing material or sealing surfaces as well as structural changes in the valve components, e.g. drive unit or valve stem, due to environmental influences (temperature, humidity, shocks, etc.).

In order to prevent any leakage that may occur in the process or to maintain the quality of the seal at a constantly high level, a valve closure is typically replaced or renewed at certain intervals. Such a maintenance interval is usually determined by the number of opening and closing cycles to be expected in a certain period of time or by the number and type of influences occurring (e.g. process gases). Maintenance is typically carried out as a precautionary measure in order to be able to exclude the occurrence of a leak as far as possible in advance.

Replacing the entire valve closure, i.e. the entire valve disk, is typically associated with considerable expense. For this purpose, the vacuum system must be at least partially vented on a regular basis so that the replacement can take place. For the replacement itself, the valve disk is separated from the actuator and a new disk is inserted. After the exchange, a subsequent evacuation and flushing of the previously ventilated part is necessary.

The invention is thus based on the object of providing an improved vacuum valve, in particular a valve closure, which reduces or avoids the above-mentioned disadvantages.

This object is solved by the realization of the characterizing features of the independent claims. Features which further form the invention in an alternative or advantageous manner are to be taken from the dependent claims.

The basic idea of the present invention is to design a valve closure in multiple parts, wherein a closure plate can be modularly and detachably attached to a support structure (carrier element). In this case, the closure plate preferably has the sealing sealant material. Maintenance can be carried out correspondingly simply by replacing only the closure plate, wherein the carrier element can remain connected to a drive unit of the vacuum valve.

The connection of the closure plate to the carrier element can be realized in particular by a clamp connection, wherein one of the two components, i.e. closure plate or carrier element, has a support and the respective other component has a retaining element as a counterpart.

The closure plate and the carrier element can preferably be designed in such a way that they can be connected to each other by pushing them together, and by or during this pushing together, a cooperation of the support with the retaining element is effected. This can generate a clamping force that presses or pulls the closure plate against the carrier element.

The support and/or the retaining element may in particular have an undercut profile for generating the clamping force, wherein the undercut profile in particular has an inclined surface relative to a connection side or sealing surface.

The invention thus relates to a vacuum valve for regulating a volume or mass flow and/or for closing and opening a valve opening. The vacuum valve has a valve seat which has the valve opening defining an opening axis and a first sealing surface surrounding the valve opening. In addition, the vacuum valve has a closure assembly for regulating the volume or mass flow and/or for closing the valve opening in a substantially gas-tight manner with a second sealing surface corresponding to the first sealing surface and via a drive unit coupled to the closure assembly, which is adapted to provide a movement of the closure assembly in such a way that the closure assembly can be adjusted from an open position, in which the closure assembly at least partially exposes the valve opening, into a closed position, in which there is sealing contact of the first sealing surface and the second sealing surface with a sealing material present therebetween and the valve opening is thereby closed in a gas-tight manner, and back.

The closure assembly comprises a carrier element having a first connection side and a closure plate having a second connection side, wherein the first and second connection sides are designed to connect the carrier element to the closure plate. The closure assembly further comprises a support and a retaining element, wherein the first connection side comprises the support and the second connection side comprises the retaining element, or the first connection side comprises the retaining element and the second connection side comprises the support.

The closure plate is brought together with the carrier element, and the support and the retaining element are designed to correspond in such a way that, by an interaction of the support with the retaining element in this brought-together state, a clamping force is generated which is directed orthogonally to an extension of at least one of the connection sides.

The retaining element protrudes from the respective connection side and has a curved boundary line for interaction with the support.

In particular, the sealing material can be provided on the first or second sealing surface. For example, the sealing material can be present as an O-ring in a groove of the closure plate or vulcanized to the closure plate.

The support can be designed in particular as a groove, especially a dovetail groove. The support can in particular provide a support line or support surface.

In particular, the support is shaped in such a way that it enables the clamping force to be generated. Alternatively or additionally, the support can be shaped in such a way that a precise relative positioning of the closure plate and the carrier element can be provided by means of the support line or support surface provided.

The closure plate and the carrier element each extend in particular mainly in a direction of extension. The direction of extension corresponds to the direction of the greatest spatial extension of the respective component. This extension can also be referred to as the respective width of the closure plate or the carrier element.

Orthogonal to the direction of extension, the respective component has a height that is typically smaller than the width.

In a third spatial direction, orthogonal to the direction of extension and height, the respective component has a thickness.

The connection system of the closure assembly can be designed in particular in such a way that the closure plate and the carrier element are brought together by being pushed together in a direction orthogonal to the direction of extension. In this case, the pushing together takes place in particular along a defining direction. During pushing together, there is preferably contact between the closure plate and the carrier element, and the two connection sides of these components are at least partially in contact during pushing together by means of the support and/or the retaining element.

When pushed together, the support and the retaining element come into effective contact. The interaction of the retaining element and the support ensures on the one hand that the closure plate is held on the carrier element and on the other that a contact pressure is generated which presses the closure plate against the carrier element. In this pushed-together state, the closure plate can be fixed to the carrier element. Fixing can be provided by applying force in the direction of pushing together, for example by means of screwing.

The application of force can press the support and the retaining element together. The two elements, support and retaining element, are preferably designed in such a way that the extent of the clamping force acting orthogonally to the connection sides can be varied as a function of the applied force. In other words, the greater the force for fixing the closure plate to the carrier element, the greater the clamping force can be.

In one embodiment, the vacuum valve the curved boundary line may have a radius of curvature r, wherein a width b of the first or the second connection side corresponds to at least twenty times the radius of curvature r. Accordingly, b≥r*20 may apply.

In particular, the boundary line defines at least part of the edge of the retaining element. In one embodiment, the boundary line may also define (i.e. at least partially enclose) the area of the retaining element that develops the clamping effect together with the support.

In one embodiment, the retaining element may have a round head shape or mushroom head shape at its end projecting from the respective connection side.

The shape of the retaining element may be provided by a body which, with increasing distance from the respective connection side, has an increasingly greater extension over a range orthogonal to the distance normal. The cross-section of the round-headed body may have the shape of a trapezoid, in particular an isosceles trapezoid.

In particular, the boundary line can be given by a perimeter of the protruding body at its greatest extension orthogonal to the distance normal.

In particular, the round-headed retaining element provides an undercut in the direction of the connection side.

In one embodiment, the boundary line may form an ellipse, a circle, or a semicircle. Alternatively, the boundary line may describe a polygon.

In one embodiment, the first or the second connection side can have a receptacle, in particular a recess or bore with an internal thread, for fastening the retaining element. This offers the advantage that the retaining element can be inserted quickly and easily on this connection side or replaced, for example, in the event of damage. For this purpose, the retaining element can have a shape corresponding to the shape and extension of the receptacle

In one embodiment, the retaining element may be fixedly connected to the respective connection side.

In one embodiment, the support may have a curved support line for interacting with the retaining element, wherein the support line has a radius of curvature r, wherein a width b of the first or second connection side corresponds to at least fifteen times the radius of curvature r. In one embodiment, the support line forms an ellipse, a circle, or a semicircle.

In particular, the support line can be designed to correspond to the boundary line of the retaining element. In this way, the course and/or the dimensioning can at least essentially correspond to that of the boundary line. In this way, clamping of the closure plate to the carrier element can be optimized so that the clamping force at defined positions of the closure plate is of a desired magnitude.

In one embodiment, the closure plate may have a fastening element projecting from its connection side for releasably connecting the closure plate to the carrier plate.

In particular, the fastening element is designed to project with respect to the connection side and has a recess, in particular a bore, extending through the fastening element for the passage of a fastening means, in particular a screw.

In one embodiment, the fastening element may include a stop aligned parallel to the direction of extension of the closure plate and the carrier element may include a centering surface corresponding to the stop, wherein interaction of the stop and the centering surface provides alignment of the closure plate relative to the carrier element.

The exact alignment can be provided by this, in particular in the direction of extension, in particular in such a way that the closure plate and the carrier element are superimposed in a desired position and/or, for example, the position of the circumference of the closure plate corresponds to the position of the circumference of the carrier element.

The fastening element, which is firmly connected to the closure plate, advantageously simplifies bringing together and joining (connecting) the closure plate and the carrier element, since the position of the fastening element can be fixed in a defined manner and a fastening counterpart can be suitably arranged and shaped on the carrier element.

Due to the projecting shape and position of the fastening element, a centering or desired positioning relative to the carrier in the mating direction (parallel to the height of the closure plate) can be predefined. This facilitates the assembly of the closure plate to the carrier element and prevents, for example, excessive pressing of the two components.

In one embodiment, the carrier element may have a first guide element extending orthogonally to the direction of extension of the carrier element, wherein the first guide element has a rectangular groove and the rectangular groove provides an undercut. The closure plate may have a second guide element, wherein the second guide element has an undercut, in particular a dovetail-shaped undercut, for connection to the rectangular groove.

In particular, the second guide element may be provided by the retaining element.

Such a guide provides an advantageous assembly aid when assembling the closure plate and carrier element. Thus, the plate can be pushed onto the carrier by means of the guide, wherein the guide already provides a relative positioning of the components.

In one embodiment, the closure assembly can have at least two, in particular four, retaining elements, wherein the second connection side has the at least two retaining elements. A simplified and facilitated alignment of the closure plate relative to the carrier element can be achieved by the multiple arrangement of retaining elements. In particular, if the retaining elements are designed as round heads (round head pins) or mushroom heads, a simple, precise and at the same time robust mating and clamping connection can be provided thereby.

In one embodiment, the vacuum valve may include a separating device for separating a process atmosphere region from an external atmosphere region.

The process atmosphere region is to be understood in particular as a region that can be defined by a process chamber. In this region, a process atmosphere, in particular a vacuum, can be produced for processing substrates. Components intended for this region must satisfy increased requirements, e.g. with regard to material resistance. Accordingly, the external atmosphere region is to be understood in particular as a region in which normal atmospheric conditions exist, e.g. room air.

The drive unit can be assigned here at least partially, in particular completely, to the external atmosphere region and the valve closure in particular to the process atmosphere region.

The separating device of the valve can be formed by a bellows, for example. The bellows can, for example, be provided inside the valve housing or the drive unit.

A valve known in the prior art and described, for example, in U.S. Pat. No. 6,772,989 has a valve body with two ports, a valve seat arranged in a flow path connecting the two ports in the flow chamber, and an opening opposite the valve seat. A piston of a pneumatic cylinder system is arranged in a valve cover that closes the opening. This piston drives a valve disk, which opens and closes the valve seat, via a valve stem. The valve cover is attached to the opening in a gas-tight manner by a bellows plate. The two ends of a bellows surrounding the valve stem are attached in a gas-tight manner to the inner edge surface of the bellows plate and to the valve disk. The valve disk has an annular retaining groove on the surface facing the valve seat, in which a sealing ring is arranged.

A valve housing is made, for example, of aluminum or stainless steel, or internally coated with aluminum or another suitable material, while the valve disk and bellows are usually made of steel. The bellows, which can be expanded and compressed along its longitudinal axis within the range of the displacement path of the disk, seals the flow chamber in an airtight manner from the valve stem and the actuator. Two main types of bellows are used. On the one hand, the diaphragm bellows, and on the other hand, the shaft bellows, the latter of which is distinguished from the diaphragm bellows by the fact that it has no welded seams and is easier to clean, but has a smaller maximum stroke.

The invention also relates to a closure assembly for a vacuum valve for regulating a volume or mass flow and/or for closing and opening a valve opening. The closure assembly has a coupling adapted to be coupled to a drive unit of the vacuum valve and a second sealing surface corresponding to a first sealing surface of a valve seat of the vacuum valve. The closure assembly further comprises a carrier element having a first connection side and a closure plate having a second connection side, wherein the first and second connection sides are designed to connect the carrier element to the closure plate. In addition, a support and a retaining element are provided, wherein the first connection side comprises the support and the second connection side comprises the retaining element, or the first connection side comprises the retaining element and the second connection side comprises the support.

The closure plate is brought together with the carrier element in such a way and the support and the retaining element are designed to correspond in such a way that a clamping force, which is directed orthogonally to an extension of at least one of the connection sides, is generated by an interaction of the support with the retaining element in this brought-together state. The retaining element projects from the respective connection side and has a curved boundary line for interaction with the support.

In one embodiment, the carrier element can have a third connection side opposite the first connection side and a further closure plate, wherein the further closure plate is connected to the carrier element by means of the third connection side, wherein a further retaining element of the closure plate or of the carrier element interacts in a clamping manner with a further support of the closure plate or of the carrier element.

At least one of the closure plates of the closure assembly, in particular both, may be present according to one of the following embodiments according to the invention.

The invention further relates to a closure plate for a closure assembly described above. The closure plate has a second sealing surface which corresponds to a first sealing surface of a valve seat of a vacuum valve, wherein the second sealing surface comprises a sealing material (seal). The closure plate further has a second connection side, wherein the second connection side is adapted for connection to a first or third connection side of a carrier element of the closure assembly and is provided on the rear side of the closure plate relative to the sealing surface. In particular, the connection side faces in an opposite direction relative to the sealing surface.

The closure plate has a retaining element, wherein the retaining element is adapted such that, when the closure plate is brought together with the carrier element, a clamping force is generated by an interaction of a support of the carrier element with the retaining element, with the clamping force being directed orthogonally to an extension of the second connection side. The retaining element projects from the second connection side and has a curved boundary line for interaction with the support.

In one embodiment, the curved boundary line may have a radius of curvature r, wherein a width b of the second connection side corresponds to at least fifteen times the radius of curvature r.

In one embodiment, the second connection side may have a receptacle, in particular a recess or bore with an internal thread, for fastening the retaining element.

In one embodiment, the retaining element may be fixedly connected to the second connection side.

In one embodiment, the retaining element may have a round-headed head at its end projecting from the second connection side.

In one embodiment, the boundary line may form an ellipse, a circle, or a semicircle.

In one embodiment, the closure plate may include a fastening element protruding from the second connection side for releasably connecting the closure plate to a carrier element of the closure assembly.

In particular, the fastening element can be designed to project with respect to the second connection side and have a recess, in particular a bore, extending through the fastening element for the passage of a fastening means, in particular a screw.

In particular, the fastening element may include a stop aligned parallel to the direction of extension of the closure plate and the carrier element may include a centering surface corresponding to the stop, wherein interaction of the stop and the centering surface provides alignment of the closure plate relative to the carrier element.

The valve according to the invention or its closure assembly is described in more detail below by way of example by means of exemplary embodiments shown schematically in the drawings. Identical elements are marked with the same reference signs in the figures. The described embodiments are generally not shown to scale and they are also not to be understood as a limitation.

The drawings show in detail:

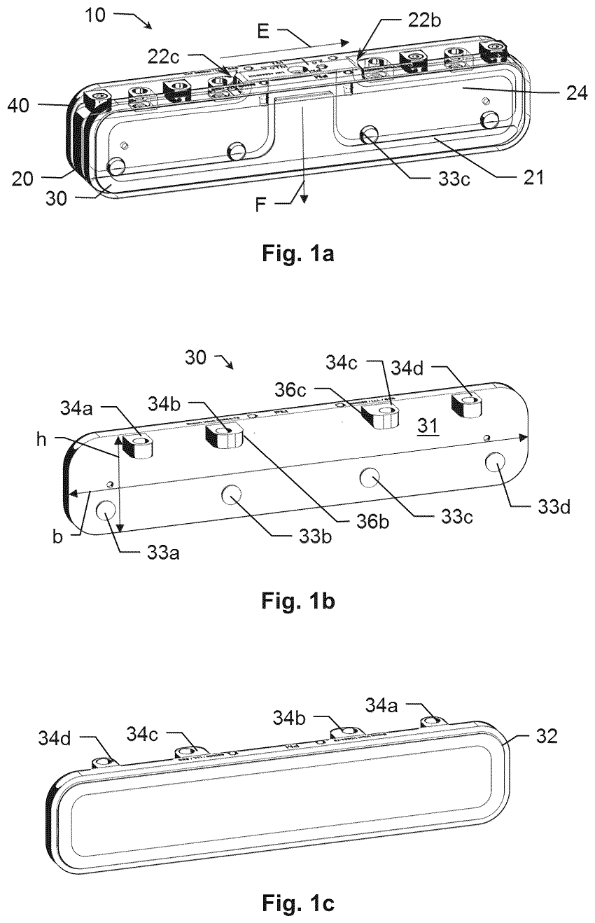

FIGS. 1a-c show a first embodiment of a closure assembly according to the invention having a carrier element and closure plate;

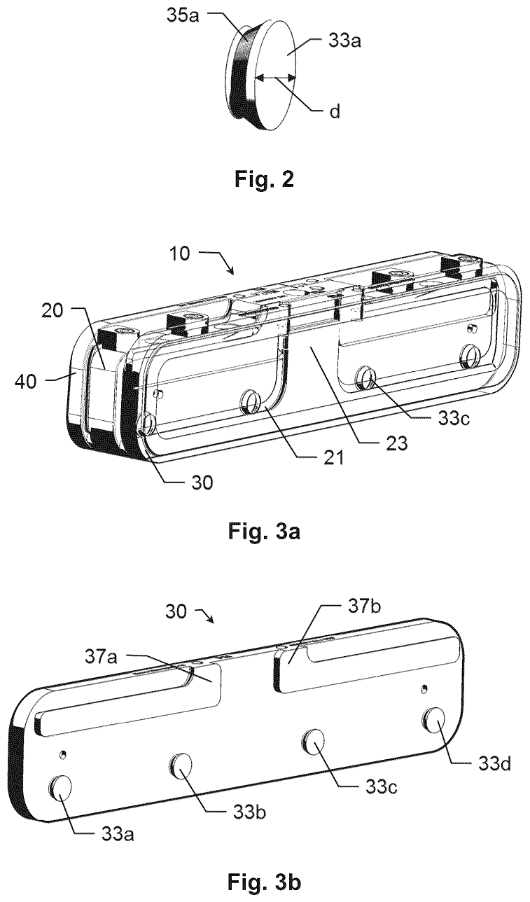

FIG. 2 shows a retaining element of a closure assembly according to the invention;

FIGS. 3a-b show a further embodiment of a closure assembly according to the invention having carrier element and closure plate;

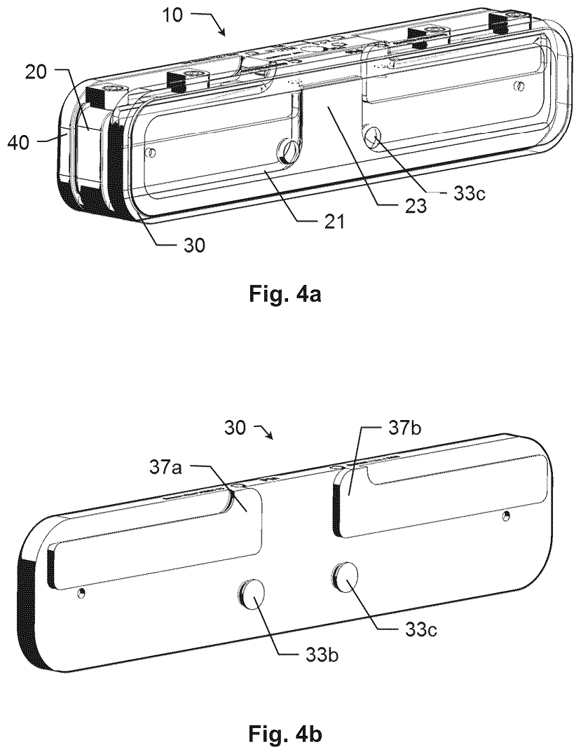

FIGS. 4a-b show a further embodiment of a closure assembly according to the invention having carrier element and closure plate;

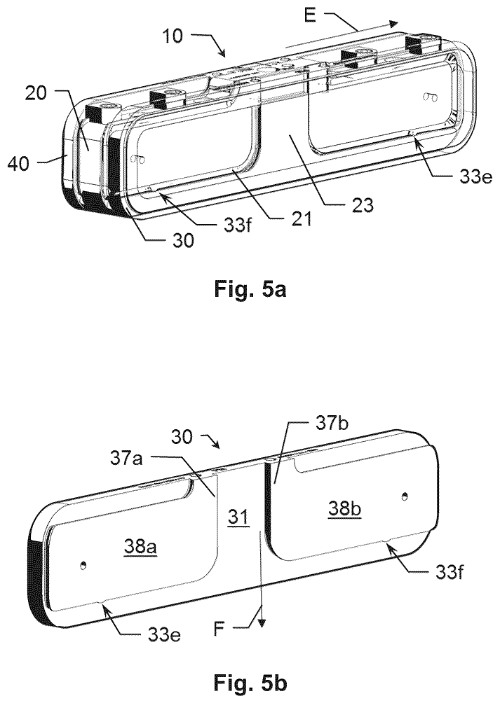

FIGS. 5a-b show a further embodiment of a closure assembly according to the invention having carrier element and closure plate;

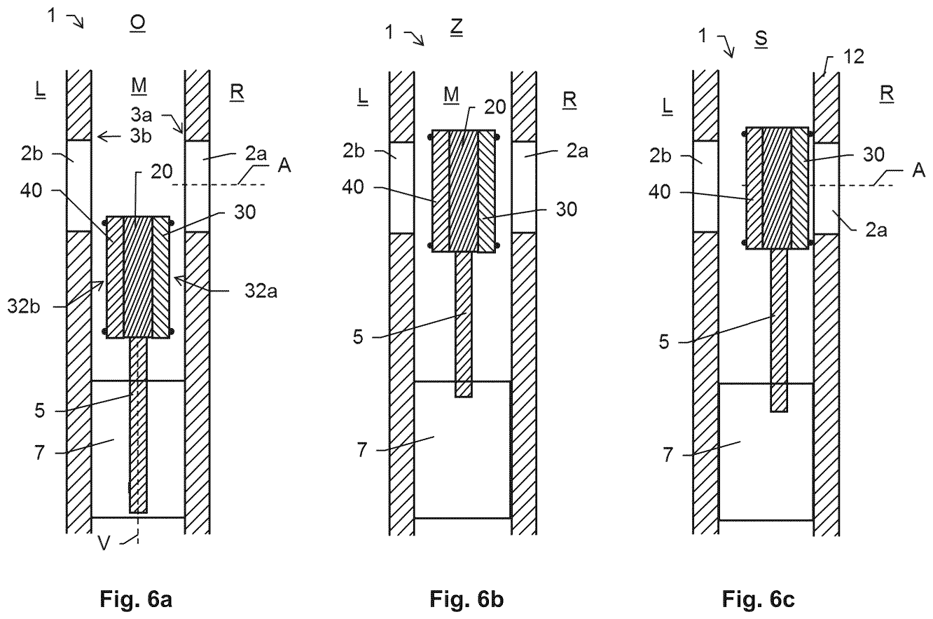

FIG. 6a-c show an embodiment of a vacuum valve according to the invention.

FIGS. 1a-1c show an embodiment of the closure assembly 10 according to the invention as well as the closure plate 30 according to the invention. FIG. 1a shows a closure assembly 10 according to the invention having a carrier element 20 and a first closure plate 30 and a second closure plate 40. The closure plate 30 is shown in a partially transparent representation in order to clarify the connection of the closure plate 30 with the carrier element 20 lying centrally between the closure plates 30, 40.

By arranging two closure plates 30 and 40 on both sides, the valve closure can provide a seal for two valve openings, in particular opposite each other. For this purpose, the valve closure can optionally be pressed against one of the openings.

FIG. 1b shows a connection side of the closure plate 30. FIG. 1c shows a sealing surface 32 of the closure plate 30 opposite the connection side 31 on the rear side. The sealing surface 32 has a circumferential seal and can thus provide a desired sealing effect.

Four retaining elements 33a-d are arranged on the connection side 31 of the closure plate 30. The retaining elements 33a-d are arranged here along a line on the connection side 31. The closure plate 30 also has four fastening elements 34a-d.

The carrier element 20 has a support 21 on its connection side 24.

The retaining elements 33a-d are arranged and shaped in such a way that they interact with the support 21 of the carrier element 20 in an assembled, joined state (cf. FIG. 1a). In this case, the retaining elements 33a-d rest on the support and effect a clamping of the closure plate 30 to the carrier element 20. A corresponding clamping force acts orthogonally to a direction of extension E of the assembled components, as well as orthogonally to a direction defining the height h of the closure plate 30. The width D of the closure plate 30 is typically defined by the extension in the direction of extension E.

To provide the clamping force, the retaining elements 33a-d in the embodiment shown are designed as round heads. FIG. 2 shows a perspective view of the round-headed retaining element 33a. The remaining retaining elements 33b-d are shaped in the same way. The round head shape provides an increasing extension with increasing distance from the closure plate 30 orthogonal to the distance.

Thus, the retaining element 33a (and in each case also the remaining retaining elements 33b-d) provides a retaining surface 35a extending obliquely with respect to the surface of the joining side. Due to the oblique course of the retaining surface 35a, the closure plate 30 is pressed against the carrier element 20 when it is brought together with the carrier element 20 by a resulting interaction with the support 21. In particular, for this purpose, the closure plate 30 is pushed in the joining direction F relative to the carrier element 20 while in existing contact with the carrier element 20. For this purpose, the support 21 can provide an inclined support surface analogous to the round head, which enables simple and precise joining of the two components.

In the joined state, the support surface and the retaining surface 35a are thus in contact, in particular the support surface and the retaining surface 35a are in surface contact.

The support 21 can be designed as an edge or groove. The support can extend over large parts of the width of the carrier element or can be designed in several parts in the form of individual segments, in particular with the number, shape and size corresponding to the retaining elements 33a-d.

The retaining elements 33a-d each have a diameter d (double radius r) at their ends, i.e. at the regions which are at the greatest distance from the connection side 31, which is smaller in relation to the width b by at least a factor of 10, in particular a factor of 15 or 20. The diameter decreases accordingly with increasing proximity to the surface of the closure plate 30.

The fastening elements 34a-d are arranged to project at the upper end of the closure plate 30. As shown with FIG. 1a, the closure plate 30 can be fastened to the carrier element 20 by means of these fastening elements 34a-d. In the embodiment shown, the closure plate 30 is screwed to the carrier element 20 by means of these fastening elements 34a-d.

The positioning of the fastening elements 34a-d also provides a limit to the mobility of the closure plate 30 relative to the carrier element 20 during assembly (pushing together) (in the joining direction F), thus enabling the definition of a relative alignment of the components. Thus, assembly can be performed easily and without much prior knowledge on the part of a user.

For equally precise alignment of the closure plate 30 relative to the carrier element 20 with respect to the direction of extension E, the fastening elements 34b and 34c have respective lateral stops 36b and 36c. The stops 36b and 36c face in opposite directions (parallel to the direction of extension E), The carrier element 20 has correspondingly interacting and corresponding centering surfaces 22b and 22c with the stops 36b and 36c.

When the carrier element 20 and the closure plate 30 are pushed together, the stops 34b-c contact the centering surfaces 22b-c, wherein the latter are shaped in such a way that a distance between the two stop surfaces 34b-c essentially corresponds to a distance between the two centering surfaces 22b-c. The horizontal alignment occurs accordingly (automatically) when the components are pushed together, thus providing a simple and reliable assembly.

FIGS. 3a and 3b show a further embodiment of the closure assembly 10 according to the invention and the closure plate 30 according to the invention.

In contrast to the embodiment according to FIGS. 1a to 1c, the closure plate 30 here has guide elements 37a and 37b instead of the fastening elements 34a-d.

In an embodiment as herein, the guide elements 37a-b may each have an undercut, which is particularly dovetail-shaped, for connection to a groove. The undercuts are provided opposite each other on the sides of the guide elements 37a-b. Accordingly, the carrier element 20 has a corresponding guide element 23 extending orthogonally to the direction of extension E of the carrier element 20. Here, the guide element 23 of the carrier element 20 has a rectangular groove on each side, and the rectangular grooves provide undercuts.

Interaction of the guide elements 37a-b with the guide element 23 provides, on the one hand, precise relative alignment of the closure plate 30 with respect to the carrier element 20 in the direction of extension E and, on the other hand, simple and reliable guidance when these two components are pushed together.

Fixing of the closure plate 30 to the carrier element 20 is here effected by separate fastening bodies which are fixed, e.g. screwed, to the upper side of the carrier element 20 and press the closure plate 30 in the joining direction F. Hereby, the clamping of the closure plate 30 to the carrier element 20 by means of interaction of the holding elements 33a-d with the support 21 as well as a holding of the closure plate 30 to the carrier element 20 by means of the guide elements is provided.

FIGS. 4a and 4b show another embodiment of the closure assembly 10 according to the invention and the closure plate 30 according to the invention.

In contrast to the embodiment according to FIGS. 3a and 3b, the closure plate 30 has only two retaining elements 33b and 33c instead of the four retaining elements 33a-d. These two retaining elements 33b and 33c are also present in a different positioning.

The two retaining elements 33b and 33c are positioned in such a way that, when the closure plate 30 is brought together with the carrier element 20, they act as guide elements on the closure plate side and engage in the grooves provided by guide elements 23 on the carrier element side. Furthermore, when the desired positioning relative to the carrier element 20 is achieved, the two retaining elements 33b and 33c come into contact with the support 21 in the joining direction F, thereby effecting clamping and precise positioning.

Furthermore, the closure plate 30 may be held to the carrier element 20 by the further guide elements 37a-b. Alternatively or additionally, the closure plate 30 can be held on the carrier element 20 by the provided fastening bodies. For this purpose, the fastening bodies may have a corresponding edge that engages with a counterpart on the closure plate 30.

FIGS. 5a and 5b show a further embodiment of the closure assembly 10 according to the invention and the closure plate 30 according to the invention.

In contrast to the preceding embodiments, the closure plate 30 has, instead of the four round-headed retaining elements 33a-d, two retaining elements 33e and 33f different therefrom. The retaining elements 33e and 33f are each formed here integrally with a joining body 38a and 38b offset from the connection side 31. The retaining elements 33e and 33f are provided on the underside of the joining bodies 38a and 38b facing in the joining direction F.

The joining bodies 38a and 38b also have lateral guide elements 37a-b for precisely guided sliding together with the carrier element 20.

In addition, the support 21 of the carrier element 20 can have recesses corresponding to the arrangement and shaping of the retaining elements 33e and 33f, whereby in the pushed-together state the retaining elements 33e and 33f are present in the recesses and, as a result of this cooperation, centering of the closure plate 30 relative to the carrier element 20, in particular in the direction of extension E, is provided. The integral design shown provides a robust and compact variant for precise and simple mounting of the closure plate 30 on the carrier element 20.

FIGS. 6a-6c show an embodiment of a vacuum valve 1 according to the invention, which is designed as a (two-sided) vacuum transfer valve 1, shown in different closed positions.

The vacuum valve 1 has a closure assembly 10 according to the invention having two closure plates (valve disks) 30 and 40. Each of the closure plates has a sealing surface 32a, 32b with a seal for gas-tight closure of the openings 2a, 2b. The openings have a cross-section corresponding to the closure plates and are designed in a valve wall. The valve wall can be, for example, the wall of a vacuum process chamber. The openings 2a, 2b are each surrounded by a valve seat 3a, 3b, which in turn also provides a sealing surface corresponding to the sealing surface of the closure plate. The sealing surfaces 32a, 32b of the closure plates 30, 40 surround the respective closure plates and have the sealing material (seal). In a closed position S (FIG. 6c), the seal is compressed between the sealing surfaces. The openings 2a, 2b connect a gas region M, with the gas regions L and R.

It is understood that the valve seats 3a, 3b together with their sealing surface may alternatively be formed as valve components structurally fixed to the valve 1 and may for example be arranged, e.g. screwed, to a chamber opening.

The closure assembly 10 can be arranged, as shown here, on an adjustment arm S, which is rod-shaped here, for example, and extends along a geometric adjustment axis V. The adjustment arm S is mechanically coupled to a drive unit 7, by means of which the closure assembly 10 can be adjusted in the first gas region M by adjusting the adjustment arm S by means of the drive unit 7 between an open position O (FIG. 6a) via an intermediate position Z (FIG. 6b) into a closed position (FIG. 6c).

In the open position O, the closure assembly 10 is outside a projection area of the openings 2a, 2b and fully exposes them, as shown in FIG. 6a.

By linearly adjusting the closure assembly 10 in the axial direction in a plane parallel to or coaxial with the adjustment axis V and parallel to the valve wall, the closure assembly 10 can be adjusted from the open position O to the intermediate position Z by means of the drive unit 7.

In this intermediate position Z (FIG. 6b), the sealing surfaces 32a, 32b are in spaced opposition to the sealing surfaces of the valve seats surrounding the openings 2a, 2b.

By adjusting in the direction of the opening axis A defined by the openings 2a, 2b (here: transversely to the adjustment axis V), therefore e.g. perpendicular to the wall and the valve seat, the closure assembly 10 can be adjusted from the intermediate position Z to the closed position S (FIG. 6c).

In the closed position S, the closure plate 30 closes the opening 2a in a gas-tight manner and separates the gas region M from the gas region R in a gas-tight manner.

The vacuum valve is opened and closed by means of the drive unit 7, in this case by an L-shaped movement in two directions of the closure assembly 10, e.g. perpendicular to each other. It is understood that, analogously to closing the opening 2a with the closure plate 30, a gas-tight sealing of the opening 2b can be provided by means of the closure plate 40 by moving the closure assembly 10 in the other direction along the axis A.

A transfer valve 1 as shown is typically provided for sealing a process volume (vacuum chamber) and for loading and unloading the volume. Frequent changes between the open position O and the closed position S are the rule in such an application. This can lead to increased wear of the sealing surfaces 32a, 32b, the seals and the mechanically moved components. Simple replacement or maintenance of the sealing elements is provided by the modular detachable arrangement of the closure plates 30 and 40 according to the invention.

It is understood that these figures shown are only schematic illustrations of possible exemplary embodiments. The various approaches can also be combined with each other and with prior art devices and methods.

1. A vacuum valve for regulating a volume of mass flow and/or for closing and opening a valve opening, comprising
a valve seat having the valve opening defining an opening axis and a first sealing surface surrounding the valve opening,
a closure assembly for regulating the volume or mass flow and/or for closing the valve opening in a substantially gas-tight manner with a second sealing surface corresponding to the first sealing surface, and
a drive unit coupled to the closure assembly and adapted to provide movement of the closure assembly such that the closure assembly is adjustable
from an open position, in which the closure assembly at least partially exposes the valve opening, into
a closed position, in which there is sealing contact of the first sealing surface and the second sealing surface with a sealing material present therebetween and the valve opening is thereby closed in a gas-tight manner, and back,
wherein:
the closure assembly comprises
a carrier element having a first connection side and a closure plate having a second connection side, wherein the first and second connection sides are designed to connect the carrier element to the closure plate,
a support and a retaining element wherein
the first connection side comprises the support and the second connection side comprises the retaining element or
the first connection side comprises the retaining element and the second connection side comprises the support,
the closure plate is brought together with the carrier element, and the support and the retaining element are designed to correspond in such a way that a clamping force, which is directed orthogonally to an extension of at least one of the connection sides, is generated by an interaction of the support with the retaining element in the brought-together state,
the retaining element projects from the respective connection side and has a curved boundary line for interaction with the support.

2. The vacuum valve according to claim 1, wherein the curved boundary line has a radius of curvature r, wherein a width b of the first or the second connection side corresponds to at least twenty times the radius of curvature r.

3. The vacuum valve according to claim 1, wherein the first or the second connection side has a receptacle, in particular a recess or bore with an internal thread, for fastening the retaining element.

4. The vacuum valve according to claim 1, wherein the retaining element is fixedly connected to the respective connection side.

5. The vacuum valve according to claim 1, wherein the retaining element has a round-headed head at its end projecting from the respective connection side.

6. The vacuum valve according claim 1, wherein the boundary line forms an ellipse, a circle or a semicircle.

7. The vacuum valve according to claim 1, wherein the support has a curved support line for cooperating with the retaining element, wherein:
the support line has a radius of curvature r, wherein a width b of the first or the second connection side corresponds to at least twenty times the radius of curvature r and/or
forms an ellipse, a circle or a semicircle.

8. The vacuum valve according to claim 1, wherein the closure plate has a fastening element projecting from its connection side for releasably connecting the closure plate to the carrier element.

9. The vacuum valve according to claim 8, wherein the fastening element is designed to project with respect to the connection side and has a recess, in particular a bore, extending through the fastening element for the passage of a fastening means, in particular a screw.

10. The vacuum valve of claim 8, wherein the fastening element has a stop aligned parallel to the direction of extension of the closure plate and the carrier element has a centering surface corresponding to the stop wherein, interaction of the stop and the centering surface causes alignment of the closure plate relative to the carrier element.

11. The vacuum valve according to claim 1, wherein:
the carrier element has a first guide element extending orthogonally to the direction of extension of the carrier element, wherein the first guide element has a rectangular groove and the rectangular groove provides an undercut; and
the closure plate has a second guide element, wherein the second guide element has an undercut, in particular dovetail-shaped undercut, for connection to the rectangular groove.

12. The vacuum valve according to claim 11, wherein the second guide element is provided by the retaining element.

13. The vacuum valve according to claim 1, wherein the closure assembly comprises at least two, in particular four, retaining elements, wherein the second connection side comprises the at least two retaining elements.

14. A closure assembly for a vacuum valve for regulating a volume or mass flow and/or for closing and opening a valve opening, comprising
a coupling adapted to be coupled to a drive unit of the vacuum valve and
a second sealing surface corresponding to a first sealing surface of a valve seat of the vacuum valve,
wherein:
a carrier element having a first connection side and a closure plate having a second connection side, wherein the first and second connection sides are designed to connect the carrier element to the closure plate, and
a support and a retaining element, wherein
the first connection side comprises the support and the second connection side comprises the retaining element or
the first connection side comprises the retaining element and the second connection side comprises the support, wherein
the closing plate is brought together with the carrier element, and the support and the retaining element are designed to correspond in such a way that a clamping force, which is directed orthogonally to an extension of at least one of the connection sides is generated by an interaction of the support with the retaining element in the brought-together state,
the retaining element projects from the respective connection side and has a curved boundary line for interaction with the support.

15. The closure assembly according to claim 14, wherein the carrier element has a third connection side opposite the first connection side and a further closure plate, wherein the further closure plate is connected to the carrier element by means of the third connection side, wherein a further retaining element of the closure plate or of the carrier element interacts in a clamping manner with a further support of the closure plate or of the carrier element.

16. The closure plate for a closure assembly according to claim 14, comprising
a second sealing surface which corresponds to a first sealing surface of a valve seat of a vacuum valve, wherein the second sealing surface comprises a sealing material,
a second connection side, wherein the second connection side is adapted for connection to a first or third connection side of a carrier element of the closure assembly and is provided on the rear side of the closure plate relative to the sealing surface,
a retaining element wherein the retaining element is adapted such that, when the closure plate is brought together with the carrier element, a clamping force is generated by an interaction of a support of the carrier element with the retaining element, with the clamping force being directed orthogonally to an extension of the second connection side, and
the retaining element projects from the second connection side and has a curved boundary line for interaction with the support.

17. The closure plate according to claim 16, wherein the curved boundary line has a radius of curvature r, wherein a width b of the second connection side corresponds to at least twenty times the radius of curvature r.

18. The closure plate according to claim 16, wherein the second connection side has a receptacle, in particular a recess or bore with an internal thread, for fastening the retaining element.

19. The closure plate according to claim 16, wherein the retaining element is fixedly connected to the second connection side.

20. The closure plate according to claim 16, wherein the retaining element has a round-headed head at its end projecting from the second connection side.

21. Closure plate according to claim 16, wherein the boundary line forms an ellipse, a circle or a semicircle.

22. The closure plate according to claim 16, wherein the closure plate comprises a fastening element protruding from the second connection side for releasably connecting the closure plate to a carrier element of the closure assembly.

23. The closure plate according to claim 22, wherein the fastening element is designed to project with respect to the second connection side and has a recess, in particular a bore, extending through the fastening element for the passage of a fastening means, in particular a screw.

24. The closure plate according to claim 22, wherein the fastening element has a stop aligned parallel to the direction of extension of the closure plate and the carrier element has a centering surface corresponding to the stop, wherein interaction of the stop and the centering surface provides alignment of the closure plate relative to the carrier element.
